(19) United States
(12) Patent Application Publication
(10) Pub. No.: US 2023/0133632 A1
(43) Pub. Date: May 4, 2023

(54) METHOD FOR MANUFACTURING A MONOCRYSTALLINE SAPPHIRE SEED AS WELL AS A SAPPHIRE SINGLE-CRYSTAL WITH A PREFERRED CRYSTALLOGRAPHIC ORIENTATION AND EXTERNAL PART AND FUNCTIONAL COMPONENTS FOR WATCHMAKING AND JEWELLERY

(71) Applicant: Comadur SA, Le Locle (CH)

(72) Inventors: Didier COCHET-MUCHY, Hurtieres (FR); Naser BERISHA, Wettingen (CH); Pierry VUILLE, Les Emibois (CH)

(73) Assignee: Comadur SA, Le Locle (CH)

(21) Appl. No.: 17/970,180

(22) Filed: Oct. 20, 2022

(30) Foreign Application Priority Data
Nov. 2, 2021 (EP) 21205897.8

(51) Int. Cl. C30B 29/20; C30B 15/34; C30B 17/00; C01F 7/02; G04B 39/00

(52) U.S. Cl. CPC C30B 29/20; C30B 15/34; C30B 17/00; C01F 7/02; G04B 39/006; C01P 2002/76

(57) ABSTRACT

A method for manufacturing a sapphire single-crystal, including melting alumina and/or sapphire in a crucible, and bringing the molten alumina and/or sapphire in contact with a monocrystalline sapphire seed to make the molten alumina and/or sapphire crystallise progressively according to a growth direction to form the sapphire single-crystal. The monocrystalline sapphire seed has a rhombohedral crystallographic structure defining three crystallographic axes [A], [C] and [M] perpendicular to each other and respectively perpendicular to the crystallographic planes. The monocrystalline sapphire seed is a plate delimited by two planar faces which extend parallel to and at a distance from each other, is obtained from an initial sapphire single-crystal which is cut so that one of the crystallographic axes of the monocrystalline sapphire plate forms with a normal to the planar faces of the monocrystalline sapphire plate an angle whose value is comprised between 5 and 85°.

### CROSS REFERENCE TO RELATED APPLICATIONS

This application claims priority to European Patent Application No. 21205897.8 filed Nov. 2, 2021.

### TECHNICAL FIELD OF THE INVENTION

The present invention relates to a method for manufacturing a monocrystalline sapphire seed with a preferred crystallographic orientation. The present invention also relates to a method for manufacturing a sapphire single-crystal with a preferred crystallographic orientation from such a monocrystalline sapphire seed. The present invention also relates to external part and functional components for watchmaking and jewellery cut in such a sapphire single-crystal.

### Technological Background

So-called monocrystalline materials consist of a unique macroscopic crystal whose size could vary from one millimetre to several metres. One of the most common uses of single-crystals is that one made in jewellery: indeed, many ornaments of jewels are made by means of single-crystals such as rubies, sapphires, diamonds, etc. However, although this is often unknown, the role of single-crystals in the field of cutting-edge technologies is essential since the silicon used in electronics and in some photovoltaic cells as well as the compounds used in quite many solid lasers are monocrystalline. From the simple laser pointer to power lasers for nuclear fusion throughout aircraft turbines or optics, the applications of monocrystalline materials are quite various.

In the form of a single-crystal, a compound may have particular optical properties such as transparency or birefringence. When pure, the alumina Al₂O₃ crystal is transparent and is commonly used for the manufacture of watch glasses in the watchmaking industry. When coloured by dopants or impurities, the alumina Al₂O₃ crystal is used as a precious stone. The chemical environment of the atoms and of the ions forming a single-crystal being perfectly defined and organised in a repetitive manner, a dopant introduced in this environment has only a few possible occupation sites available thereto, which enables this dopant to confer a very specific property on the single-crystal. For example, when a monocrystalline material is doped to make a laser emission source out of it, the dopant is distributed over a limited number of sites, so that the energy emitted by the dopant during its electronic transitions varies only lowly, which allows obtaining a fine laser emission. Similarly, the specific definition of the sites that a dopant could occupy in a monocrystalline dopant allows modifying the property inherent to the presence of such a dopant. For example, the presence of Cr³⁺ ions in an alumina crystal is at the origin of the red colouration of ruby, whereas a beryl (Be₃Al₂Si₆O₁₈) with the same Cr³⁺ ion will be green; this will then be called emerald.

Hence, the presence of defects, in the form of dopants, in a monocrystalline compound is desired for technological applications. However, the same is not true for uncontrolled impurities, structural defects such as dislocations and fractures. Hence, in general, one seeks to use single-crystals with the highest possible quality. It is possible to find single-crystals in nature, but these are generally rare and very defective. This is why numerous synthesis techniques have been developed since the beginning of the XXth century. There exists several type of processes to obtain an artificial single-crystal:
from an oversaturated solution of the compound;
from the molten compound;
by chemical vapour deposition.

We focus herein on the synthesis of single-crystals by crystallisation in the molten state which represents close to 80% of the obtained artificial single-crystals. The first method for crystallising monocrystalline compounds in the molten state is due to the French Auguste Verneuil. Suggested in 1891 while Verneuil looked to synthesise rubies for jewellery-making, the method consists in making the molten material crystallise in contact with a fraction of a single-crystal called seed obtained beforehand. To synthesise corundum of formula Al₂O₃ which composes rubies and sapphires, it is necessary to rise to a very high temperature (melting temperature at 2,050° C.), a temperature that is reached by means of an oxyhydrogen torch H₂+½ O₂→H₂O whose flame temperature is about 2,700° C. Alumina, possibly doped, is introduced in the form of fine powder by a vibrator which drops small amounts thereof directly in the flame of the torch. The molten alumina drop thus formed falls at the top of the seed and crystallises following the crystallographic arrangement of this seed. The growing single-crystal is progressively lowered for the crystallisation to be done at a constant temperature. At the end of synthesis, a single-crystal in the form of a bottle is obtained.

Verneuil process is still used to date, almost identically, in particular for the industrial production of corundum for jewellery-making and watchmaking (rubies, sapphires, watch glasses, etc.). Although it generates single-crystals that are more defective than those obtained by other methods, Verneuil process has the advantage of being relatively less expensive and quick; by means of this method, it is for example possible to obtain a single-crystal in about ten hours. Nevertheless, the sapphire single-crystals obtained by Verneuil process have high dislocation densities and uncontrollable local disorientations. In turn, other defects also present in Verneuil single-crystals such as bubbles, webs and other inclusions could be seen with the naked eye for example in a finished watch glass.

The present invention focuses on methods for synthesising single-crystals by crystallisation in the molten state in a crucible. In particular, the invention focuses on techniques for growing single-crystals of the EFG, HEM, Kyropoulos, Czochralski, Bridgman Vertical, Bridgman Horizontal and Micro Pulling Down type.

Suggested by J. Czochralski in 1915, the process bearing the same name is an emblematic method for crystallising single-crystals in the molten state. Based on the same principle as Verneuil process, namely melting of the material and crystalline growth in contact with a monocrystalline seed obtained beforehand, Czochralski process nevertheless differs from Verneuil process in that the material to be molten is input in whole and molten at the beginning of the experiment instead of being input progressively in small amount. For this purpose, the material to be molten is placed in a crucible made of a chemically-inert material and withstanding high temperatures such as, inter alia, platinum or iridium. The crucible is placed at the centre of electrically-conductive windings through which a high-frequency current flows, which allows heating the crucible by induction. Once the material is molten and the temperature stabilised, a monocrystalline seed obtained beforehand is placed on a refractory rod and brought into contact with the molten material. Afterwards, the seed is slowly raised towards a cooler area where the molten material crystallises in contact with the seed. Thus, the single-crystal is pulled from the molten material. The refractory rod is continuously rotating in order to homogenise the molten material layer that is about to crystallise.

In Czochralski process, the temperature control should be careful because we should set very close to melting of the material to be crystallised yet without the temperature being too high, because this would cause melting of the seed which would be lost. However, the difficulty in implementing Czochralski process is compensated by the high quality of the crystals it generates, which makes it a proven crystal growth technique from this perspective.

Thanks to its exceptional physical properties, sapphire having the chemical composition Al₂O₃ is suitable for countless applications. Sapphire is the hardest and the most resistant material after diamond and can, therefore, be used in the watchmaking industry and also in industries for high-performances fields. Synthetic sapphire is inert, transparent in the polished state, acid-resistant, with a low electrical conductivity and, with a melting point of more than 2,000° C., is suitable for the most demanding uses. Sapphire is almost indestructible and resists, in practice, to all external aggressions. Watch glasses and technical components made of sapphire resist scratches, their surface is non-porous, shiny and their transparency is perfect once polished.

As described hereinabove, the methods for synthesising single-crystals by crystallisation in the molten state in a crucible allow making high-quality monocrystalline sapphires. Nevertheless, these methods are expensive because the quality of the desired crystals requires growth rates that are generally slower as well as a tooling such as the crucibles that is larger in number and more complex. Thus, the duration of manufacturing a Czochralski single-crystal may be in the range of one week or more. This is why it is desired to produce single-crystals that are as defect-free as possible.

Watch glasses are obtained by machining blanks cut in a sapphire single-crystal. Yet, to date, sapphire single-crystals produced by crystallisation in the molten state in a crucible are obtained by growing these single-crystals according to a direction corresponding to one of the main crystallographic axes, generally [A] or [M] of the sapphire. These crystalline growth modes currently lead to blanks whose normal to the surface is the crystallographic axis [A] or [M] with the crystallographic axis [C] contained in this surface. Yet, it has been found that with such a crystallographic orientation, the blanks have a greater fragility to machining, which leads to more chipping. Hence, the watch glasses are more difficult to machine and the scrap rate is higher, which substantially increases the cost price of such glasses.

### SUMMARY OF THE INVENTION

The present invention aims to overcome the above-mentioned problems as well as other ones by providing a method for manufacturing sapphire single-crystals allowing obtaining sapphire single-crystals that are less defective and easier to machine.

As a preliminary remark, it is important to understand that the monocrystalline sapphire seeds that will be considered hereinafter are cut specifically in a first sapphire single-crystal, then these monocrystalline sapphire seeds are used afterwards to make second sapphire single-crystals grow in which the desired glass blanks will be cut.

To this end, the present invention relates to a method for manufacturing a monocrystalline sapphire seed, this monocrystalline sapphire seed having a rhombohedral crystallographic structure defining three crystallographic axes [A], [C] and [M] perpendicular to each other and respectively perpendicular to the crystallographic planes A (11-20), C (0001) and M (10-10), this monocrystalline sapphire seed being a plate delimited by two planar faces which extend parallel to and at a distance from each other, this monocrystalline sapphire plate being obtained from an initial sapphire single-crystal that is cut so that one of the crystallographic axes [A], [C] or [M] of the monocrystalline sapphire plate forms with a normal to the planar faces of this monocrystalline sapphire plate an angle whose value is comprised between 5 and 85°.

According to a special embodiment, the present invention also relates to a method for manufacturing a monocrystalline sapphire seed, this monocrystalline sapphire seed having a rhombohedral crystallographic structure defining three crystallographic axes [A], [C] and [M] perpendicular to each other and respectively perpendicular to the crystallographic planes A (11-20), C (0001) and M (10-10) of the rhombohedral structure, this monocrystalline sapphire seed being a bar obtained beforehand from an initial sapphire single-crystal which is cut so that one of the crystallographic axes [A], [C] or [M] of the resulting monocrystalline sapphire bar forms with a normal to a cross-section of this monocrystalline sapphire bar an angle whose value is comprised between 5 and 85°.

According to another special embodiment, the present invention also relates to a method for manufacturing a sapphire single-crystal, this method comprising the step of melting alumina and/or sapphire in a crucible, then bringing the melting alumina and/or sapphire in contact with a monocrystalline sapphire seed in the form of a plate or a bar in order to make the melting alumina and/or sapphire crystallise progressively according to a growth direction to form the sapphire single-crystal.

According to another special embodiment, the present invention also relates to a method for manufacturing a sapphire single-crystal obtained by crystallisation in the molten state at a top of a die, this method comprising the step of melting alumina and/or sapphire in a crucible, then in bringing throughout channels of the die the molten alumina and/or sapphire in contact with a monocrystalline sapphire seed obtained beforehand in order to make the molten alumina and/or sapphire crystallise progressively according to a growth direction to form the sapphire single-crystal, the monocrystalline sapphire seed having a rhombohedral crystallographic structure defining three crystallographic axes [A], [C] and [M] perpendicular to each other and respectively perpendicular to the crystallographic planes A (11-20), C (0001) and M (10-10) of the rhombohedral structure, the monocrystalline sapphire seed being a first plate delimited by two planar faces which extend parallel to and at a distance from each other, one of the crystallographic axes [A], [C] or [M] being perpendicular to the planar faces of the first monocrystalline sapphire plate, this first monocrystalline sapphire plate being inclined by an angle whose value is comprised between 5 and 85° with respect to a perpendicular to the plane defined by the channels of the die, the sapphire single-crystal resulting from the crystalline growth being a second monocrystalline sapphire plate delimited by two planar faces which extend parallel to and at a distance from each other, this second monocrystalline sapphire plate having a disorientation of its crystallographic axes [A], [M] or [C] with respect to the normal to its planar faces which corresponds to the inclination of the first plate with respect to the channels of the die.

According to particular implementations of the method according to the invention:
the crystallographic axis [A] or [M] or [C] forms with the normal to the planar faces of the monocrystalline sapphire plate an angle whose value is comprised between 25 and 35°;
the crystallographic axis [A] or [M] or [C] forms with the normal to the planar faces of the monocrystalline sapphire plate an angle whose value is comprised between 5 and 15°;
the crystallographic axis [A] or [M] or [C] forms with the normal to the cross-section of the monocrystalline sapphire bar an angle whose value is comprised between 25 and 35°;
the crystallographic axis [A] or [M] or [C] forms with the normal to the cross-section of the monocrystalline sapphire bar an angle whose value is comprised between 5 and 15°;
the method for manufacturing the sapphire single-crystal is selected from among the EFG, HEM, Kyropoulos, Czochralski, Bridgman Vertical, Bridgman Horizontal and Micro Pulling Down processes;
the alumina and/or the sapphire that are molten are pure or doped;
sapphire scraps are used;
once the sapphire single-crystal is obtained, external part or functional components for watchmaking or jewellery are cut in this sapphire single-crystal;
the external part or functional components are watch bridges, plates, glasses, cases and dials or else wristlet links.

According to another special embodiment, the present invention relates to a method for manufacturing a monocrystalline sapphire cylinder, this method comprising the step of performing, by means of a cutting tool, in a sapphire single-crystal ball that has been grown according to one of the crystallographic axes [A] or [M] or [C] a core drilling according to a direction which forms with the growth crystallographic axis of the sapphire single-crystal ball an angle whose value is comprised between 5 and 85°.

The invention also relates to a monocrystalline sapphire seed having a rhombohedral crystallographic structure defining three crystallographic axes [A], [C] and [M] perpendicular to each other and respectively perpendicular to the crystallographic planes A (11-20), C (0001) and M (10-10) of the rhombohedral structure, this monocrystalline sapphire seed being a plate delimited by two planar faces which extend parallel to and at a distance from each other, one of the crystallographic axes of the monocrystalline sapphire plate forming with a normal to the planar faces of this monocrystalline sapphire plate an angle whose value is comprised between 5 and 85°.

The invention also relates to a monocrystalline sapphire seed having a rhombohedral crystallographic structure defining three crystallographic axes [A], [C] and [M] perpendicular to each other and respectively perpendicular to the crystallographic planes A (11-20), C (0001) and M (10-10) of the rhombohedral structure, this monocrystalline sapphire seed being monocrystalline sapphire bar one of the crystallographic axes of which forms with a normal to a cross-section of this monocrystalline sapphire bar an angle whose value is comprised between 5 and 85°.

The invention also relates to a watch glass blank delimited by two faces which extend at a distance from each other and at least one of which is planar, this blank being made of monocrystalline sapphire having a rhombohedral crystallographic structure defining three crystallographic axes [A], [C] and [M] perpendicular to one another and respectively perpendicular to the crystallographic planes A (11-20), C (0001) and M (10-10) of the rhombohedral structure, one of the crystallographic axes forming with a normal to the planar face of the blank an angle whose value is comprised between 5 and 85°, so that the crystallographic axis is not comprised in the planar face of the blank.

Finally, the invention relates to external part and functional components for watchmaking and jewellery, in particular watch bridges, plates, glasses, cases and dials or else wristlet links, cut in a sapphire single-crystal obtained in accordance with the method of the invention.

Thanks to these features, the present invention provides a method that allows manufacturing watch glasses in facilitated machining conditions. More specifically, the watch glasses obtained thanks to the method according to the invention are cut in sapphire single-crystals obtained by crystalline growth in contact with a monocrystalline sapphire seed in the form of a plate or a bar which is machined so that one of the crystallographic axes [A], [C] or [M] of the monocrystalline sapphire plate or bar forms with the normal to the planar faces of the plate, respectively with the normal to a cross-section of the bar, an angle comprised between 5 and 85°. The blanks of watch glasses that are cut in a sapphire single-crystal obtained by implementing the method according to the invention have one of their crystallographic axes [A], [C] or [M] angularly shifted with respect to a normal to their surface by the same value as the disorientation of one of the crystallographic axes [A], [C] or [M] of the sapphire seed from which the sapphire single-crystal in which these blanks are cut is obtained. Consequently, the angular shift of the crystallographic axis [A], [C] or [M] with respect to the normal to the planar faces of the plate or of the cross-section of the monocrystalline sapphire bar which serves as a seed for the crystalline growth of the sapphire single-crystal results in that the crystallographic axis [C] is not generally comprised in the plane of the blanks of the watch glasses, so that the greatest fragility to machining that is usually encountered at the locations where this crystallographic axis [C] crosses the edges of the blanks of the watch glasses is generally avoided. Hence, the blanks of watch glasses are less hard and consequently easier to machine. In particular, given the fact that these blanks of watch glasses are less fragile, the risks that the edges of these blanks chip during machining are considerably reduced. Furthermore, the watch glasses obtained thanks to the method of the invention have little, and possibly no, dislocations and local and uncontrolled changes in orientation of the sapphire single-crystal.

### BRIEF DESCRIPTION OF THE FIGURES

Other features and advantages of the present invention will appear more clearly from the following detailed description of an example of implementation of the method according to the invention, this example being given only for purely illustrative and non-limiting purposes with reference to the appended drawings wherein:

FIG. 1 illustrates an EFG-type crystalline growth method enabling the obtainment of several sapphire single-crystals from a monocrystalline sapphire seed in the form of a plate prepared in accordance with the invention;

FIG. 2 illustrates a watch glass blank cut in a sapphire single-crystal obtained by crystalline growth in contact with a monocrystalline sapphire seed in the form of a plate prepared in accordance with the invention;

FIG. 3 illustrates a monocrystalline sapphire seed in the form of a bar prepared in accordance with the invention;

FIG. 4A illustrates a so-called Kyropoulos ball that has been grown according to the crystallographic axis [A] and in which a bar is sampled which will serve as a seed for the growth of a sapphire single-crystal in accordance with the invention;

FIG. 4B illustrates a sapphire single-crystal in the form of a Kyropoulos ball obtained by means of the seed of FIG. 4A and in which a cylinder is sampled by means of a diamond tool and according to the growth direction of this sapphire single-crystal allowing obtaining blanks of watch glasses in accordance with the invention;

FIG. 4C illustrates a so-called Kyropoulos ball in which a cylinder is directly sampled by means of a diamond tool allowing obtaining blanks of watch glasses in accordance with the invention;

FIG. 5 is a top view of a die for the growth of sapphire single-crystals in accordance with another embodiment of the method according to the invention;

FIG. 6 is a side sectional view of the die of FIG. 5;

FIG. 7 is a top view of a watch glass obtained thanks to the method according to the invention and placed between two crossed polarisers;

FIG. 8 schematically illustrates cutting of blanks of watch glasses in an EFG-type sapphire single-crystal;

FIG. 9 schematically illustrates cutting of blanks of watch glasses in a monocrystalline sapphire cylinder.

### DETAILED DESCRIPTION OF THE INVENTION

The present invention is based on the inventive general idea which consists in producing watch glasses in particular from a blank cut in a sapphire single-crystal obtained by crystalline growth in the molten state in a crucible in contact with a monocrystalline sapphire seed in the form of a plate or a bar. The originality of the invention lies in particular in that the monocrystalline sapphire seed that is used to make the sapphire single-crystal grow in which the glass blanks are cut is, itself, cut in a sapphire single-crystal so that the crystallographic axis [C] that is perpendicular to the crystallographic plane (0001) of the primitive cell of the sapphire single-crystal in which these glass blanks are cut is not contained in the plane of the latter. More specifically, the first sapphire single-crystal is cut so that a monocrystalline sapphire seed is obtained in the form of a plate with planar faces wherein one of the crystallographic axes [A], [C] or [M] forms with a normal to the planar faces of the plate, respectively with a cross-section of the bar, an angle whose value is comprised between 5 and 85°. Next, the disorientation of the crystallographic axes [A], [C] or [M] in the monocrystalline sapphire seed is found in the sapphire single-crystal that is grown in contact with this monocrystalline sapphire seed, then in the blanks of watch glasses that are cut in this sapphire single-crystal. Finally, the crystallographic axis [C] does not lie in the plane of the glass blanks and therefore does not cross the edges of these blanks. Thus, the greatest fragility to machining that is usually noticed when the crystallographic axis [C] crosses the edges of the blanks of the watch glasses is avoided. Thus, the blanks of watch glasses are less fragile and consequently easier to machine. In particular, the risks of chipping are considerably reduced.

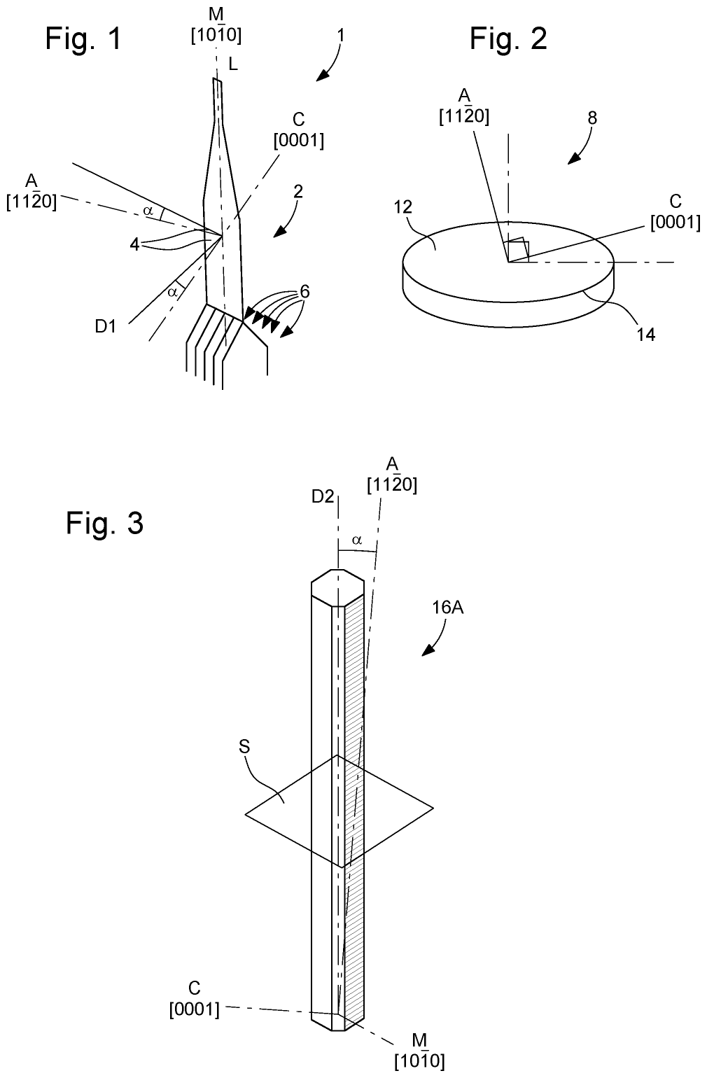

FIG. 1 schematically shows an EFG-type method for the manufacture of a sapphire single-crystal by means of a monocrystalline sapphire seed obtained in accordance with the invention. Referred to by the reference numeral 1, the monocrystalline sapphire seed is in the form of a plate 2 delimited by two planar faces 4 which extend parallel to and at a distance from each other. This monocrystalline sapphire seed 1 has a rhombohedral crystallographic structure defining three crystallographic axes [A], [C] and [M] perpendicular to each other and respectively perpendicular to the crystallographic planes A (11-20), C (0001) and M (10-10) of the primitive cell of sapphire.

According to the invention, the monocrystalline sapphire seed 1 is cut in a first sapphire single-crystal so that, for example, the crystallographic axis [C] of the resulting plate 2 is rotated about the crystallographic axis [M] to form with a normal D1 to the planar faces 4 of this plate 2 an angle α whose value is comprised between 5 and 85°, for example 10°. The crystallographic axes [A], [C] and [M] being perpendicular to each other, the crystallographic axis [A] is also shifted by the same angle α with respect to the planar faces 4 of the plate 2, whereas the crystallographic axis [M] rotates by 10° about itself and therefore does not move.

It should be noted that the techniques for cutting a monocrystalline sapphire seed in a sapphire single-crystal according to a preferred direction are known to a person skilled in the art in the field of sapphire single-crystal growth and therefore will not be detailed herein.

As it arises from FIG. 1, the monocrystalline sapphire seed 1 is pulled according to the crystallographic axis [M] which defines the growth direction L of sapphire single-crystals 6. Each sapphire single-crystal 6 is obtained by bringing molten alumina and/or sapphire in contact with the monocrystalline sapphire seed 1 at one of the tops of a die, then by progressively pulling this monocrystalline sapphire seed 1 according to the growth direction L to slowly bring it away from the molten alumina and/or sapphire and enable the progressive growth of the sapphire single-crystal 6.

In accordance with the invention, the monocrystalline sapphire seed 1 is used to make the sapphire single-crystals 6 grow in which the blanks 8 of watch glasses 10 will be cut. These blanks 8 of watch glasses 10 are delimited by two faces which extend at a distance from each other and at least one of which 12 is planar. The monocrystalline sapphire seed 1 is in the form of a plate 2 itself cut in an initial sapphire single-crystal so that, for example, its crystallographic axis [C] is rotated about the crystallographic axis [M] to form with a normal D1 to the planar faces 4 of the plate 2 an angle α whose value is comprised between 5 and 85°, for example 10°. Next, the disorientation of the crystallographic axes [A] and [C] in the monocrystalline sapphire seed 1 is found in the sapphire single-crystals 6 that are grown in contact with this monocrystalline sapphire seed 1, then in the blanks 8 of watch glasses 10 that are cut in these sapphire single-crystals 6.

Finally, as shown in FIG. 2, because of the disorientation of the crystallographic axes [A] and [C], the crystallographic axis [C] is not comprised in the planar face 12 of the blanks 8 of the watch glasses 10 and therefore does not cross the edges 14 of these blanks 8. Thus, the greatest fragility to machining that is usually noticed at the locations where this crystallographic axis [C] crosses the edges 14 of the blanks 8 of the watch glasses 10 is avoided. Thus, the blanks 8 of the watch glasses 10 are less fragile and consequently easier to machine. In particular, the risks of chipping are considerably reduced and the losses are lesser.

FIG. 3 schematically shows a monocrystalline sapphire bar 16A used in a crystalline growth process for example of the Kyropoulos type. This monocrystalline sapphire bar 16A has a rhombohedral crystallographic structure defining three crystallographic axes [A], [C] and [M] perpendicular to each other and respectively perpendicular to the crystallographic planes A (11-20), C (0001) and M (10-10) of the primitive cell of sapphire.

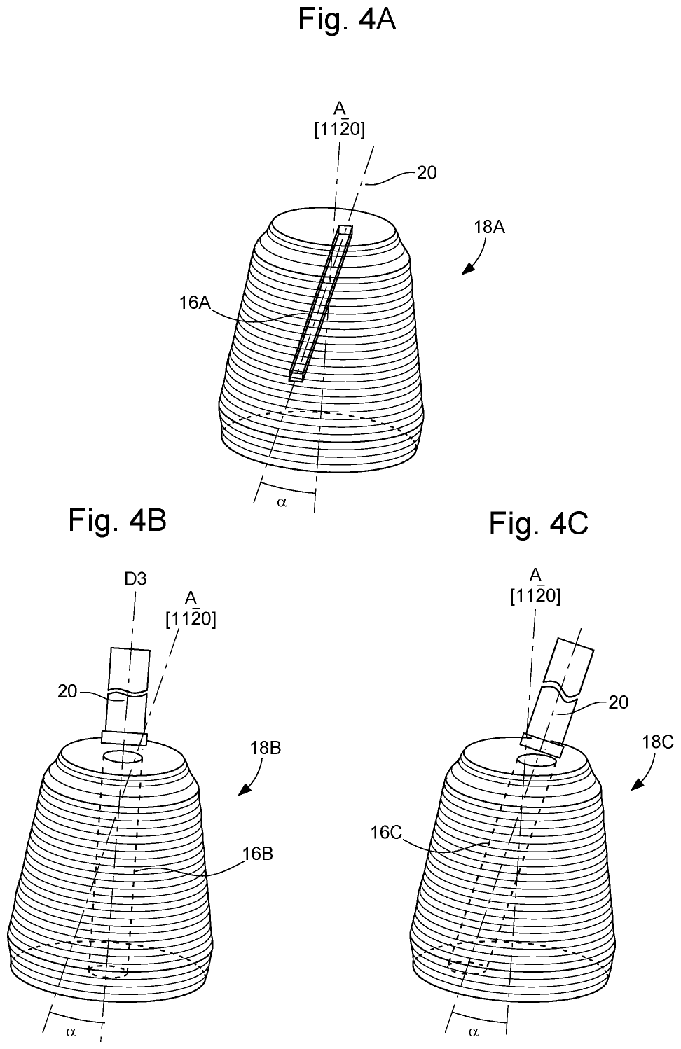

According to the invention and as illustrated in FIG. 4A, the monocrystalline sapphire bar 16A is cut in a sapphire single-crystal ball 18A obtained beforehand, so that for example the crystallographic axis [A] of the resulting monocrystalline sapphire bar 16A is rotated about the crystallographic axis [M] to form with a normal D2 to a cross-section S of this monocrystalline sapphire bar 16A an angle α whose value is comprised between 5 and 85°, for example 10°. The crystallographic axes [A], [C] and [M] being perpendicular to each other, the crystallographic axis [C] is also shifted by the same angle α with respect to the cross-section S of the monocrystalline sapphire bar 16A, whereas the crystallographic axis [M] rotates about itself and therefore does not move. Next (cf. FIG. 4B), the disorientation of the crystallographic axes [A] and [C] in the monocrystalline sapphire bar 16A is found in the sapphire single-crystal ball 18B that is grown by setting molten alumina and/or sapphire in contact with this monocrystalline sapphire bar 16A. Next, it is possible to cut, by means of a diamond cutting tool 20, a monocrystalline sapphire cylinder 16B in the sapphire single-crystal ball 18B according to the growth direction D3 of the latter from the monocrystalline sapphire bar 16A. Afterwards, blanks 8 of watch glasses 10 in accordance with the invention may, in turn, be cut in this monocrystalline sapphire cylinder 16B.

In FIG. 4C, one could see a sapphire single-crystal ball 18C for example of the Kyropoulos type in which a core drilling is performed by means of the cutting tool 20 according to a direction which forms with the crystallographic axis [A] of growth of this sapphire single-crystal ball 18C an angle α whose value is comprised between 5 and 85°, for example 10°. By this means, monocrystalline sapphire cylinders 16C enabling cutting of blanks 8 of watch glasses 10 in accordance with the invention could also be obtained.

It should be noted that the techniques for cutting according to a preferred direction a monocrystalline sapphire seed in a sapphire single-crystal ball obtained beforehand, for example of the Kyropoulos type, whether this seed is in the form of a plate 2 with planar faces 4 or in the form of a bar 16A, are known to a person skilled in the art in the field of sapphire single-crystal growth and therefore will not be detailed herein.

Finally, because of the disorientation of the crystallographic axis [A] with respect to the normal to a cross-section S of the monocrystalline sapphire bar 16A, the crystallographic axis [C] does not generally lie in the planar face 12 of the blanks 8 of the watch glasses 10 and therefore does not generally cross the edges 14 of these blanks 8. Thus, the greatest fragility that is usually noticed at the locations where this crystallographic axis [C] crosses the edges 14 of the blanks 8 of the watch glasses 10 is avoided. Thus, the blanks 8 of the watch glasses 10 are less fragile and consequently easier to machine. In particular, the risks of chipping are considerably reduced and the losses are lesser.

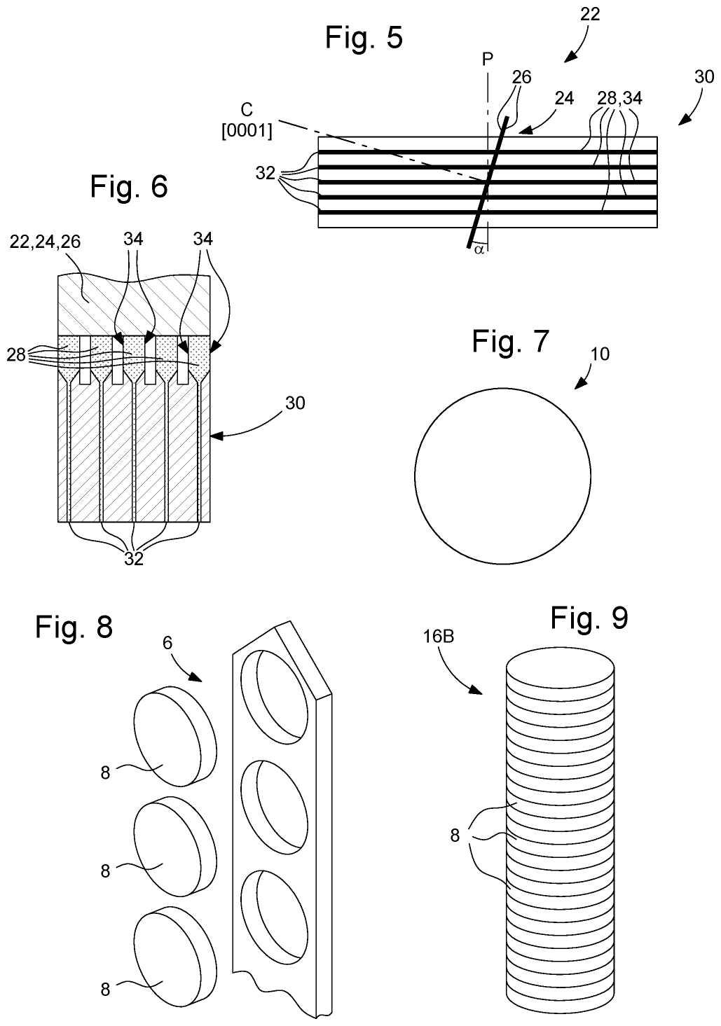

It goes without saying that the present invention is not limited to the modes of implementation that have just been described and that various simple modifications and variants could be considered without departing from the scope of the invention as defined by the appended claims. In particular, rather than preparing a monocrystalline sapphire seed in the form of a plate a crystallographic axis of which forms a non-zero angle with respect to the normal to the planar faces that delimit this plate as explained hereinabove, it may also be considered, as illustrated in FIGS. 5 and 6, to use a monocrystalline sapphire seed 22 in the form of a first plate 24 the crystallographic axis [C] of which for example is conventionally perpendicular to the planar faces 26 that delimit this first plate 24. According to a special embodiment of the invention, such a monocrystalline sapphire seed 22 is used to make sapphire single-crystals 28 grow at the tops of a die 30 which is composed by a plurality of channels 32 which extend parallel to and at a distance from each other and inside which molten alumina and/or sapphire transits. Afterwards, this molten alumina and/or sapphire comes into contact with the monocrystalline sapphire seed 22 and starts crystallising to form the sapphire single-crystals 28 in the form of second plates. Each of these second monocrystalline sapphire plates is delimited by two planar faces 34 which extend parallel to and at a distance from each other. In this case, by inclining the monocrystalline sapphire seed 22 by an angle α whose value is comprised between 5 and 85°, for example 10°, with respect to a perpendicular P to the plane in which the channels 32 of the die 30 extend, the second monocrystalline sapphire plates which result from the crystalline growth have the same disorientation of their crystallographic axis [A] with respect to the normal to their planar faces 34 as the plates obtained by means of a monocrystalline sapphire seed having a disorientation of its crystallographic axes as described hereinabove with reference to FIG. 1.

FIG. 7 is a top view of a watch glass 10 obtained thanks to the method of the invention and placed between two crossed polarisers. In this FIG. 7, one could see that no defect such as dislocations or uncontrolled local changes in orientation is visible in the watch glass 10. It should also have been understood that, in accordance with the method of the invention, alumina and/or sapphire are molten. These materials may be pure or doped. Preferably yet without limitation, the doping materials are selected from the group formed by titanium, iron, chromium, cobalt and vanadium used alone or in combination. As regards the used sapphire, it preferably consists of scraps such as poor-quality sapphire crystals or else machining chips or scraps originating from the different steps of manufacturing the watch glasses 10. The present invention has been described quite particularly in connection with the manufacture of watch glasses 10. It goes without saying that this example is given only for purely illustrative and-limiting purposes and that the present invention applies more generally to the manufacture of external part and functional components in particular for watchmaking and jewellery such as watch bridges, plates, cases and dials or else wristlet links.

As illustrated in FIG. 8, blanks 8 of watch glasses 10 are cut in an EFG-type sapphire single-crystal 6. As illustrated in FIG. 9, it should be understood that the blanks 8 of watch glasses 10 are machined in a monocrystalline sapphire cylinder 16B cut in the sapphire single-crystal ball 18B according to the growth direction D3 of the latter from the monocrystalline sapphire bar 16A. In other words, the blanks 8 of watch glasses 10 are cut perpendicularly to the growth direction D3 of the sapphire single-crystal ball 18B. Typically, the thickness of the blanks 8 of watch glasses 10 is comprised between 1 to 2 mm and could reach 10 mm. Finally, it should be noted that, in all of the foregoing, the term “bar” applies to a seed, and the term “cylinder” applies to a sapphire single-crystal.

### NOMENCLATURE

1. Monocrystalline sapphire seed
2. Plate
4. Planar faces
a Angle
D1 Normal
L Growth direction
6. Sapphire single-crystal
8. Blanks
10. Watch glasses
12. Planar face
14. Edges
16A. Monocrystalline sapphire bar
16B. Monocrystalline sapphire cylinder
16C. Monocrystalline sapphire cylinder
18A. Sapphire single-crystal ball
18B. Sapphire single-crystal ball
18C. Sapphire single-crystal ball
D2 Normal
S Cross-section
D3 Growth direction
20. Cutting tool
22. Monocrystalline sapphire seed
24. First plate
26. Planar faces
28. Sapphire single-crystals
30. Die
32. Channels
34. Planar faces

1. A method for manufacturing a monocrystalline sapphire seed, the monocrystalline sapphire seed having a rhombohedral crystallographic structure defining three crystallographic axes [A], [C] and [M] perpendicular to each other and respectively perpendicular to the crystallographic planes A (11-20), C (0001) and M (10-10), the monocrystalline sapphire seed being a plate delimited by two planar faces which extend parallel to and at a distance from each other, the monocrystalline sapphire plate being obtained from an initial sapphire single-crystal that is cut so that one of the crystallographic axes [A], [C] or [M] of the monocrystalline sapphire plate forms with a normal to the planar faces of the monocrystalline sapphire plate an angle whose value is comprised between 5 and 85°.

2. A method for manufacturing a monocrystalline sapphire seed, the monocrystalline sapphire seed having a rhombohedral crystallographic structure defining three crystallographic axes [A], [C] and [M] perpendicular to each other and respectively perpendicular to the crystallographic planes A (11-20), C (0001) and M (10-10) of the rhombohedral structure, the monocrystalline sapphire seed being a monocrystalline sapphire bar obtained beforehand from an initial sapphire single-crystal which is cut so that one of the crystallographic axes [A], [C] or [M] of the monocrystalline sapphire bar forms with a normal to a cross-section of the monocrystalline sapphire bar an angle whose value is comprised between 5 and 85°.

3. A method for manufacturing a sapphire single-crystal, the method comprising the step of melting alumina and/or sapphire in a crucible, then bringing the melting alumina and/or sapphire in contact with a monocrystalline sapphire seed obtained by implementing the method according to claim 1 in order to make the melting alumina and/or sapphire crystallise progressively according to a growth direction to form the sapphire single-crystal.

4. A method for manufacturing a sapphire single-crystal, the method comprising the step of melting alumina and/or sapphire in a crucible, then bringing the melting alumina and/or sapphire in contact with a monocrystalline sapphire seed obtained by implementing the method according to claim 2 in order to make the melting alumina and/or sapphire crystallise progressively according to a growth direction to form the sapphire single-crystal.

5. A method for manufacturing a monocrystalline sapphire cylinder, the monocrystalline sapphire cylinder having a rhombohedral crystallographic structure defining three crystallographic axes [A], [C] and [M] perpendicular to each other and respectively perpendicular to the crystallographic planes A (11-20), C (0001) and M (10-10) of the rhombohedral structure, the method comprising the step of performing, by means of a cutting tool, in a sapphire single-crystal ball that has been grown according to one of the crystallographic axes [A] or [M] or [C] a core drilling according to a direction which forms with the growth crystallographic axis of the sapphire single-crystal ball an angle whose value is comprised between 5 and 85°.

6. A method for manufacturing a sapphire single-crystal obtained by crystallisation in the molten state at a top of a die, the method comprising the step of melting alumina and/or sapphire in a crucible, then bringing throughout channels of the die the molten alumina and/or sapphire in contact with a monocrystalline sapphire seed obtained beforehand in order to make the molten alumina and/or sapphire crystallise progressively according to a growth direction to form the sapphire single-crystal, the monocrystalline sapphire seed having a rhombohedral crystallographic structure defining three crystallographic axes [A], [C] and [M] perpendicular to each other and respectively perpendicular to the crystallographic planes A (11-20), C (0001) and M (10-10) of the rhombohedral structure, the monocrystalline sapphire seed being a first plate delimited by two planar faces which extend parallel to and at a distance from each other, one of the crystallographic axes [A], [C] or [M] being perpendicular to the planar faces of the first monocrystalline sapphire plate, the first monocrystalline sapphire plate being inclined by an angle whose value is comprised between 5 and 85° with respect to a perpendicular to the plane defined by the channels of the die, the sapphire single-crystal resulting from the crystalline growth being a second monocrystalline sapphire plate delimited by two planar faces which extend parallel to and at a distance from each other, the second monocrystalline sapphire plate having a disorientation of one of its crystallographic axes [A], [M] or [C] with respect to the normal to its planar faces which corresponds to the inclination by the angle of the first plate with respect to the channels of the die.

7. The manufacturing method according to claim 3, wherein the crystallographic axis [A], [M] or [C] forms with the normal to the planar faces of the monocrystalline sapphire plate an angle whose value is comprised between 25 and 35°.

8. The manufacturing method according to claim 4, wherein the crystallographic axis [A], [M] or [C] forms with the normal to the planar faces of the monocrystalline sapphire plate an angle whose value is comprised between 25 and 35°.

9. The manufacturing method according to claim 7, wherein the crystallographic axis [A], [M] or [C] forms with the normal to the planar faces of the monocrystalline sapphire plate an angle whose value is comprised between 5 and 15°.

10. The manufacturing method according to claim 8, wherein the crystallographic axis [A], [M] or [C] forms with the normal to the planar faces of the monocrystalline sapphire plate an angle whose value is comprised between 5 and 15°.

11. The manufacturing method according to claim 3, wherein the crystallographic axis [A], [M] or [C] forms with the normal to the cross-section of the monocrystalline sapphire bar an angle whose value is comprised between 25 and 35°.

12. The manufacturing method according to claim 4, wherein the crystallographic axis [A], [M] or [C] forms with the normal to the cross-section of the monocrystalline sapphire bar an angle whose value is comprised between 25 and 35°.

13. The manufacturing method according to claim 11, wherein the crystallographic axis [A], [M] or [C] forms with the normal to the cross-section of the monocrystalline sapphire bar an angle whose value is comprised between 5 and 15°.

14. The manufacturing method according to claim 12, wherein the crystallographic axis [A], [M] or [C] forms with the normal to the cross-section of the monocrystalline sapphire bar an angle whose value is comprised between 5 and 15°.

15. The manufacturing method according to claim 3, wherein the method for manufacturing the sapphire single-crystal is selected from among the EFG, HEM, Kyropoulos, Czochralski, Bridgman Vertical, Bridgman Horizontal and Micro Pulling Down processes.

16. The manufacturing method according to claim 4, wherein the method for manufacturing the sapphire single-crystal is selected from among the EFG, HEM, Kyropoulos, Czochralski, Bridgman Vertical, Bridgman Horizontal and Micro Pulling Down processes.

17. The manufacturing method according to claim 5, wherein the method for manufacturing the sapphire single-crystal is selected from among the EFG, HEM, Kyropoulos, Czochralski, Bridgman Vertical, Bridgman Horizontal and Micro Pulling Down processes.

18. The manufacturing method according to claim 6, wherein the method for manufacturing the sapphire single-crystal is selected from among the EFG, HEM, Kyropoulos, Czochralski, Bridgman Vertical, Bridgman Horizontal and Micro Pulling Down processes.

19. The manufacturing method according to claim 15, wherein the alumina and/or the sapphire that are molten are pure or doped.

20. The manufacturing method according to claim 19, wherein sapphire scraps are used.

21. The manufacturing method according to claim 3, wherein, once the sapphire single-crystal is obtained, external part or functional components for watchmaking or jewellery are cut in the sapphire single-crystal.

22. The manufacturing method according to claim 4, wherein, once the sapphire single-crystal is obtained, external part or functional components for watchmaking or jewellery are cut in the sapphire single-crystal.

23. The manufacturing method according to claim 5, wherein, once the sapphire single-crystal is obtained, external part or functional components for watchmaking or jewellery are cut in the sapphire single-crystal.

24. The manufacturing method according to claim 6, wherein, once the sapphire single-crystal is obtained, external part or functional components for watchmaking or jewellery are cut in the sapphire single-crystal.

25. The manufacturing method according to claim 21, wherein the external part or functional components are watch bridges, plates, cases and dials or else wristlet links.

26. A monocrystalline sapphire seed having a rhombohedral crystallographic structure defining three crystallographic axes [A], [C] and [M] perpendicular to each other and respectively perpendicular to the crystallographic planes A (11-20), C (0001) and M (10-10) of the rhombohedral structure, the monocrystalline sapphire seed being a plate delimited by two planar faces which extend parallel to and at a distance from each other, one of the crystallographic axes [A], [C] or [M] of the monocrystalline sapphire plate forming with a normal to the planar faces of the monocrystalline sapphire plate an angle whose value is comprised between 5 and 85°.

27. A monocrystalline sapphire seed having a rhombohedral crystallographic structure defining three crystallographic axes [A], [C] and [M] perpendicular to each other and respectively perpendicular to the crystallographic planes A (11-20), C (0001) and M (10-10) of the rhombohedral structure, the monocrystalline sapphire seed being monocrystalline sapphire bar one of the crystallographic axes [A], [C] or [M] of which forms with a normal to a cross-section of the monocrystalline sapphire bar an angle whose value is comprised between 5 and 85°.

28. A watch glass blank delimited by two faces which extend at a distance from each other and at least one of which is planar, the blank being made of monocrystalline sapphire having a rhombohedral crystallographic structure defining three crystallographic axes [A], [C] and [M] perpendicular to one another and respectively perpendicular to the crystallographic planes A (11-20), C (0001) and M (10-10) of the rhombohedral structure, one of the crystallographic axes [A], [C] or [M] forming with a normal to the planar face of the blank an angle whose value is comprised between 5 and 85°, so that the crystallographic axis [C] is not comprised in the planar face of the watch glass blank.

29. External part and functional components for watchmaking and jewellery cut in a sapphire single-crystal obtained by implementing the manufacturing method according to claim 3.

30. External part and functional components for watchmaking and jewellery cut in a sapphire single-crystal obtained by implementing the manufacturing method according to claim 4.

31. External part and functional components for watchmaking and jewellery cut in a sapphire single-crystal obtained by implementing the manufacturing method according to claim 5.

32. External part and functional components for watchmaking and jewellery cut in a sapphire single-crystal obtained by implementing the manufacturing method according to claim 6.

33. The external part and functional components according to claim 29, wherein these consist of watch bridges, plates, glasses, cases and dials or else of wristlet links.
